(19) United States
(12) Patent Application Publication
(10) Pub. No.: US 2025/0141223 A1
(43) Pub. Date: May 1, 2025

(54) ELECTRONIC APPARATUS

(71) Applicants: Hefei ESWIN Computing Technology Co., Ltd., Heifei City (CN); Beijing ESWIN Computing Technology Co., Ltd., Beijing (CN)

(72) Inventors: Jiajhang WU, Hefei City (CN); Jangjin NAM, Hefei City (CN); Zhewei JIANG, Heifei City (CN)

(73) Assignees: Hefei ESWIN Computing Technology Co., Ltd., Heifei City (CN); Beijing ESWIN Computing Technology Co., Ltd., Beijing (CN)

(21) Appl. No.: 18/926,843

(22) Filed: Oct. 25, 2024

(30) Foreign Application Priority Data
Oct. 27, 2023 (CN) 202311412642.8

(51) Int. Cl. H02H 9/04

(52) U.S. Cl. CPC H02H 9/046

(57) ABSTRACT

The embodiment of the disclosure provides an electronic device, which includes a functional circuit portion, an electrostatic protection circuit portion, and an external circuit portion. The electrostatic protection circuit portion is configured to electrically connect the functional circuit portion and the external circuit portion to transmit electrical signals, and provide electrostatic protection to the external circuit portion. The external circuit portion includes at least one external terminal and an external control circuit portion that is electrically connected to the external terminal, and the external control circuit portion is configured to control whether the electrical signal is transmitted to the external terminal. The electrostatic protection circuit portion is configured to use the external control circuit portion for electrostatic discharge.

### CROSS-REFERENCE TO RELATED APPLICATIONS

The present application claims priority of the Chinese Patent Application No. 202311412642.8, filed on Oct. 27, 2023, the disclosure of which is incorporated herein by reference in its entirety as part of the present application.

### TECHNICAL FIELD

One or more embodiments of the present disclosure relate to an electronic apparatus.

### BACKGROUND

For electronic apparatuses including integrated circuits (ICs), electrostatic discharge (ESD) is one of the important factors contributing to early failure and limiting the operational lifespan of semiconductor devices. In general, ESD includes the phenomenon of sudden electrical discharge between two objects that carry different charges, for example, caused by the electric charge on the human body or the surface of a device. ESD can carry several amperes of current in a short period of time, causing irreversible damage to electronic components. Therefore, in the manufacture of integrated circuits, the design and use of electronic products, various measures need to be taken to prevent the occurrence of electrostatic discharge, to ensure the reliability and stability of products.

### SUMMARY

At least one embodiment of the present disclosure provides an electronic apparatus. The electronic apparatus includes a functional circuit portion, an electrostatic protection circuit portion, and an external circuit portion. The electrostatic protection circuit portion is configured to electrically connect the functional circuit portion and the external circuit portion to transmit an electrical signal, and provide electrostatic protection for the external circuit portion. The external circuit portion includes at least one external terminal and an external control circuit portion that is electrically connected to the external terminal, and the external control circuit portion is configured to control whether the electrical signal is transmitted to the external terminal. The electrostatic protection circuit portion is configured to use the external control circuit portion to perform electrostatic discharge.

For example, in the electronic apparatus provided by at least one embodiment of the present disclosure, the electrostatic protection circuit portion includes a connection circuit portion and a discharge path portion, the connection circuit portion electrically connects the functional circuit portion and the external control circuit portion to transmit the electrical signal, and is configured to prevent static electricity from being transmitted to the functional circuit portion; the discharge path portion is electrically connected to the connection circuit portion through the external control circuit portion and is configured to provide an electrostatic discharge path.

For example, in the electronic apparatus provided by at least one embodiment of the present disclosure, the external control circuit portion includes a first transistor of type N and a second transistor of type P, and the at least one external terminal includes a first external terminal, a source electrode of the first transistor is electrically connected to the connection circuit portion, and a drain electrode of the first transistor is electrically connected to the first external terminal, a source electrode of the second transistor is electrically connected to the connection circuit portion, and a drain electrode of the second transistor is electrically connected to the first external terminal, and a gate electrode of the first transistor and a gate electrode of the second transistor are configured to receive respectively a pair of control signals which are inverted; the discharge path portion includes a first diode and a second diode, the first diode is arranged between the drain electrode of the first transistor and a substrate of the first transistor, the drain electrode of the first transistor is determined as a cathode of the first diode, and the substrate of the first transistor is determined as an anode of the first diode and is configured to receive a first power supply voltage; the second diode is between the drain electrode of the second transistor and a substrate of the second transistor, the drain electrode of the second transistor is determined as an anode of the second diode, the substrate of the second transistor is determined as the cathode of the second diode and is configured to receive a second power supply voltage, and the first power supply voltage is lower than the second power supply voltage.

For example, in the electronic apparatus provided by at least one embodiment of the present disclosure, the connection circuit portion includes a first connection resistor, and a resistance value of the first connection resistor is set to be greater than an on-resistance value of the first diode and an on-resistance value of the second diode.

For example, in the electronic apparatus provided by at least one embodiment of the present disclosure, the functional circuit portion includes a first functional transistor of type N and a second functional transistor of type P, and a drain electrode of the first functional transistor and a drain electrode of the second functional transistor are electrically connected to the first connection resistor.

For example, in the electronic apparatus provided by at least one embodiment of the present disclosure, the first diode at least partially includes a parasitic diode between the drain electrode of the first transistor and the substrate of the first transistor, and the second diode at least partially includes a parasitic diode between the drain electrode of the second transistor and the substrate of the first transistor.

For example, in the electronic apparatus provided by at least one embodiment of the present disclosure, the external control circuit portion includes a third transistor of type N, a fourth transistor of type N, a fifth transistor of type P and a sixth transistor of type P, and the at least one external terminal includes a first external terminal and a second external terminal, a source electrode of the third transistor is electrically connected to the connection circuit portion, and a drain electrode of the third transistor is electrically connected to the first external terminal, a source electrode of the fourth transistor is electrically connected to the connection circuit portion, and a drain electrode of the fourth transistor is electrically connected to the second external terminal, a source electrode of the fifth transistor is electrically connected to the connection circuit portion, and a drain electrode of the fifth transistor is electrically connected to the first external terminal, a source electrode of the sixth transistor is electrically connected to the connection circuit portion, and a drain electrode of the sixth transistor is electrically connected to the second external terminal, a gate electrode of the third transistor and a gate electrode of the sixth transistor are configured to receive respectively a first pair of control signals which are inverted to each other, a gate electrode of the fourth transistor and a gate electrode of the fifth transistor are configured to receive respectively a second pair of control signals which are inverted to each other, the discharge path portion includes a third diode, a fourth diode, a fifth diode and a sixth diode, the third diode is arranged between the drain electrode of the third transistor and a substrate of the third transistor, the drain electrode of the third transistor is determined as a cathode of the third diode, the substrate of the third transistor is determined as an anode of the third diode and is configured to receive a first power supply voltage, the fourth diode is between the drain electrode of the fourth transistor and a substrate of the fourth transistor, the drain electrode of the fourth transistor is determined as an anode of the fourth diode, the substrate of the fourth transistor is determined as a cathode of the fourth diode and is configured to receive the first power supply voltage, the fifth diode is between the drain electrode of the fifth transistor and a substrate of the fifth transistor, the drain electrode of the fifth transistor is determined as a cathode of the fifth diode, the substrate of the fifth transistor is determined as an anode of the fifth diode and is configured to receive a second power supply voltage, the sixth diode is between the drain electrode of the sixth transistor and a substrate of the sixth transistor, the drain electrode of the sixth transistor is determined as an anode of the sixth diode, the substrate of the sixth transistor is determined as a cathode of the sixth diode and is configured to receive the second power supply voltage, and the first power supply voltage is lower than the second power supply voltage.

For example, in the electronic apparatus provided by at least one embodiment of the present disclosure, the functional circuit portion includes a first functional circuit sub-portion and a second functional circuit sub-portion, the connection circuit portion includes a second connection resistor and a third connection resistor, the second connection resistor is connected between the first functional circuit sub-portion, and the source electrode of the third transistor and the source electrode of the fourth transistor, and a resistance value of the second connection resistor is set to be greater than an on-resistance value of the third diode and an on-resistance value of the fourth diode, the third connection resistor is connected between the second functional circuit sub-portion, and the source electrode of the fifth transistor and the source electrode of the sixth transistor, and a resistance value of the third connection resistor is set to be greater than an on-resistance value of the fifth diode and an on-resistance value of the sixth diode.

For example, in the electronic apparatus provided by at least one embodiment of the present disclosure, the first functional circuit sub-portion includes a third functional transistor of type N and a fourth functional transistor of type P, and a drain electrode of the third functional transistor and a drain electrode of the fourth functional transistor are electrically connected to the second connection resistor, the second functional circuit sub-portion includes a fifth functional transistor of type N and a sixth functional transistor of type P, and a drain electrode of the fifth functional transistor and a drain electrode of the sixth functional transistor are electrically connected to the third connection resistor.

For example, in the electronic apparatus provided by at least one embodiment of the present disclosure, the third diode at least partially includes a parasitic diode between the drain electrode of the third transistor and the substrate of the third transistor, the fourth diode at least partially includes a parasitic diode between the drain electrode of the fourth transistor and the substrate of the fourth transistor, the fifth diode at least partially includes a parasitic diode between the drain electrode of the fifth transistor and the substrate of the fifth transistor, and the sixth diode at least partially includes a parasitic diode between the drain electrode of the sixth transistor and the substrate of the sixth transistor.

### BRIEF DESCRIPTION OF DRAWINGS

In order to illustrate the technical solutions of the embodiments of the present disclosure more clearly, the drawings of the embodiments are briefly described below, and it is obvious that the drawings described below refer only to some embodiments of the present disclosure and are not limited to the present disclosure.

FIG. 1A illustrates a schematic diagram of a single-channel output circuit portion of an electronic apparatus;

FIG. 1B illustrates a schematic diagram of a dual-channel output circuit portion of an electronic apparatus;

FIG. 2A illustrates a schematic diagram of a single-channel output circuit portion according to at least one embodiment of the present disclosure;

FIG. 2B illustrates a schematic diagram of a dual-channel output circuit portion according to at least one embodiment of the present disclosure; and

FIG. 3 illustrates an exemplary layout schematic diagram (left) of the single-channel output circuit portion illustrated in FIG. 1A and an exemplary layout schematic diagram (right) of the single-channel output circuit portion according to at least one embodiment of the present disclosure illustrated in FIG. 2A.

### DETAILED DESCRIPTION

In order to make the purpose, technical solution and advantages of the embodiments of the present disclosure clearer, the technical solutions of the embodiments of the present disclosure will be clearly and completely described below in conjunction with the accompanying drawings of the embodiments of the present disclosure. Obviously, the embodiments described are some embodiments of the present disclosure, not all embodiments. Based on the embodiments of the present disclosure described, all other embodiments obtained by a person skilled in the art without creative labor are within the scope of protection of the present disclosure.

Unless otherwise defined, the technical or scientific terms used in this disclosure shall have the ordinary meaning understood by persons with general skills in the field to which this disclosure belongs. The terms “first”, “second” and similar expressions used in this disclosure do not indicate any order, number or importance, but only to distinguish the different components. Words such as “include” or “comprise” mean that the element or object that precedes the word includes the element or object listed after the word and its equivalents, and does not exclude other elements or objects. Similar terms such as “connect” or “connected” are not limited to physical or mechanical connections, but may include electrical connections, whether direct or indirect. “Up”, “Down”, “Left”, “Right”, etc., are only used to indicate the relative positional relationship, and when the absolute position of the object being described changes, the relative positional relationship may also change accordingly.

The present disclosure is illustrated below by several specific embodiments. In order to keep the following descriptions of the embodiments of the present disclosure clear and concise, the detailed descriptions of known functions and known components may be omitted. When any component of the present disclosure embodiment appears in more than one drawing, the component is indicated by the same or similar reference number in each drawing.

In a hybrid process design, it is important to adjust the manufacturing process to maintain sufficient breakdown voltage for the high-voltage devices while preventing breakdown caused by the application of high voltages. However, it may lead to a lower current drive capability of these devices. Moreover, during the electrostatic discharge (ESD) design phase, designers may need to increase the area occupied by the devices to ensure that the discharge capability meets ESD specifications. Therefore, ESD protection circuit occupies a large percentage of the total chip size.

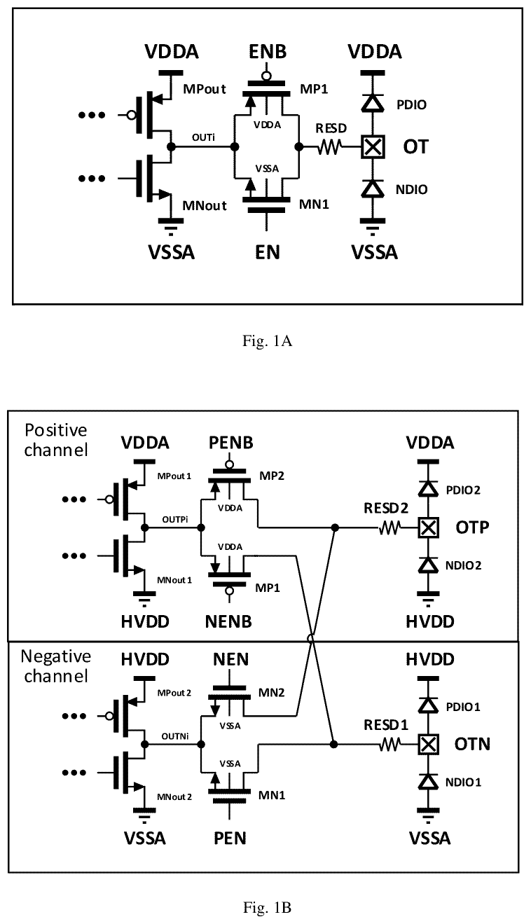

FIG. 1A illustrates a schematic diagram of a single-channel output circuit portion of an electronic apparatus; and FIG. 1B illustrates a schematic diagram of a dual-channel output circuit portion of an electronic apparatus.

As illustrated in FIG. 1A, the single-channel output circuit portion of the electronic apparatus includes a functional circuit portion, an external control circuit portion, an electrostatic protection circuit portion and an external terminal.

Herein, for example, an output stage for buffering is used as an example of the functional circuit portion, and the example of the output stage includes a N-type transistor MNout and a P-type transistor MPout. The drain electrode of the N-type transistor MNout and the drain electrode of the P-type transistor MPout are electrically connected to each other to output a signal OUTi, the source electrode of the N-type transistor MNout is connected to the first power supply voltage terminal VSSA, the source electrode of the P-type transistor MPout is connected to the second power supply voltage terminal VDDA, and the voltage of the first power supply voltage terminal VSSA is lower than the voltage of the second power supply voltage terminal VDDA, e.g. the voltage of the first power supply voltage terminal VSSA is the ground voltage. The gate electrode of the N-type transistor MNout and the gate electrode of the P-type transistor MPout receive a signal from inside a buffer to generate the output signal OUTi.

An example of the external control circuit portion includes a N-type transistor MN1 and a P-type transistor MP1. The source electrode of the N-type transistor MN1 and the source electrode of the P-type transistor MP1 are electrically connected to each other to receive the output signal OUTi. The drain electrode of the N-type transistor MN1 and the drain electrode of the P-type transistor MP1 are electrically connected to each other to output the signal OUTi. The gate electrode of the N-type transistor MN1 receives a control signal EN, and the gate electrode of the P-type transistor MP1 receives a control signal ENB, and the control signals EN and ENB are inverted to each other. Therefore, the N-type transistor MN1 and the P-type transistor MP1 select whether to transmit the signal OUTi to the external terminal OT under the control of the control signals EN and ENB.

The external terminal OT is, for example, a transmission pad of a chip, and is electrically connected to other apparatuses (such as printed circuit boards, etc.) to output the signal OUTi.

The electrostatic protection circuit portion is configured to provide electrostatic protection for the output circuit, and includes a connection resistor RESD and a combination of discharge diodes. The connection resistor RESD is connected between the external terminal OT and the external control circuit portion, and is electrically connected to the drain electrode of the N-type transistor MN1 and the drain electrode of the P-type transistor MP1 to receive the output signal OUTi. The combination of discharge diodes includes a diode PDIO and a diode NDIO to form a discharge path to release the static electricity generated on the external terminal OT. The anode of the diode PDIO is electrically connected to the external terminal OT and the cathode of the diode PDIO is electrically connected to the second power supply voltage terminal VDDA, and the cathode of the diode NDIO is electrically connected to the external terminal OT and the anode of the diode NDIO is electrically connected to the first power supply voltage terminal VSSA. The resistance value of the connection resistor RESD is greater than the on-resistance value of the diode PDIO and the on-resistance value of the diode NDIO, so that when the static electricity is generated on the external terminal OT, the static electricity is released to the first power supply voltage terminal VSSA or the second power supply voltage terminal VDDA through the diode PDIO or the diode NDIO, instead of being released to the external control circuit portion through the connection resistor RESD, which avoids affecting the output stage.

As illustrated in FIG. 1B, the dual-channel output circuit of the electronic apparatus includes a functional circuit portion, an external control circuit portion, an electrostatic protection circuit portion and two external terminals.

Herein, for example, an output stage for buffering is used as an example of the functional circuit portion, and a channel of the example of the output stage includes a N-type transistor MNout1 and a P-type transistor MPout1. The drain electrode of the N-type transistor MNout1 and the drain electrode of the P-type transistor MPout1 are electrically connected to each other to output a signal OUTPi. The source electrode of the N-type transistor MNout1 is connected to the third power supply voltage terminal HVDD, the source electrode of the P-type transistor MPout1 is connected to the second power supply voltage terminal VDDA, and the voltage of the third power supply voltage terminal HVDD is lower than the voltage of the second power supply voltage terminal VDDA. The gate electrode of the N-type transistor MNout1 and the gate electrode of the P-type transistor MPout1 receive a signal from inside the buffer to generate an output signal OUTPi.

Another channel of the example of the output stage includes a N-type transistor MNout2 and a P-type transistor MPout2. The drain electrode of the N-type transistor MNout2 and the drain electrode of the P-type transistor MPout2 are electrically connected to each other to output a signal OUTNi. The source electrode of the N-type transistor MNout2 is connected to the first power supply voltage terminal VSSA, the source electrode of the P-type transistor MPout2 is connected to the third power supply voltage terminal HVDD, and the voltage of the third power supply voltage terminal HVDD is greater than the voltage of the first power supply voltage terminal VSSA. The gate electrode of the N-type transistor MNout2 and the gate electrode of the P-type transistor MPout2 receive a signal from inside the buffer to generate the output signal OUTNi.

In an example of the external control circuit portion, the above two channels respectively include a pair of N-type transistors MN and a pair of P-type transistors MP. The source electrodes of the pair of N-type transistors MN1 and MN2 are electrically connected to each other to receive the output signal OUTNi, and the source electrodes of the pair of P-type transistors MP1 and MP2 are electrically connected to each other to receive the output signal OUTPi. The gate electrode of the N-type transistor MN1 receives a control signal PEN, and the gate electrode of the N-type transistor MN2 receives a control signal NEN. The gate electrode of the P-type transistor MP1 receives a control signal NENB, and the gate electrode of the P-type transistor MP2 receives a control signal PENB. The control signals NEN and NENB are inverted to each other, and the control signals PEN and PENB are inverted to each other.

Two external terminals, OTP and OTN, such as transmission pads of a chip, are electrically connected to other apparatuses (such as printed circuit boards, etc.), and correspond to the above two channels to output the signals OUTPi and OUTNi respectively.

The electrostatic protection circuit portion is configured to provide electrostatic protection for the output circuit, and includes connection resistors RESD1 and RESD2 that respectively correspond to the two channels and a combination 1 of discharge diodes and a combination 2 of discharge diodes.

The connection resistor RESD1 is connected between an external terminal OTN and the external control circuit portion, and is electrically connected to the drain electrode of the N-type transistor MN1 and the drain electrode of the P-type transistor MP1 to receive the output signal OUTNi or the output signal OUTPi. The combination 1 of discharge diodes includes a diode PDIO1 and a diode NDIO1 to form a discharge path to release the static electricity generated on the external terminal OTN. The anode of the diode PDIO1 is electrically connected to the external terminal OTN and the cathode of the diode PDIO1 is electrically connected to the third power supply voltage terminal HVDD. The cathode of the diode NDIO1 is electrically connected to the external terminal OTN and the anode of the diode NDIO1 is electrically connected to the first power supply voltage terminal VSSA. The resistance value of the connection resistor RESD1 is greater than the on-resistance value of the diode PDIO1 and the on-resistance value of the diode NDIO1, so that when the static electricity is generated on the external terminal OTN, the static electricity is released to the first power supply voltage terminal VSSA or the third power supply voltage terminal HVDD through one of the diode PDIO1 and the diode NDIO1, instead of being released to the external control circuit portion through the connection resistor RESD1, which avoids affecting the output stage.

The connection resistor RESD2 is connected between the external terminal OTP and the external control circuit portion, and is electrically connected to the drain electrode of the N-type transistor MN2 and the drain electrode of the P-type transistor MP2 to receive the output signal OUTPi or the output signal OUTNi. The combination 2 of discharge diodes includes a diode PDIO2 and a diode NDIO2 to form a discharge path to release the static electricity generated on the external terminal OTP. The anode of the diode PDIO2 is electrically connected to the external terminal OTP and the cathode of the diode PDIO2 is electrically connected to the second power supply voltage terminal VDDA, and the cathode of the diode NDIO2 is electrically connected to the external terminal OTP and the anode of the diode NDIO2 is electrically connected to the third power supply voltage terminal HVDD. The resistance value of the connection resistor RESD2 is greater than the on-resistance value of the diode PDIO2 and the on-resistance value of the diode NDIO2, so that when the static electricity is generated on the external terminal OTP, the static electricity is released to the third power supply voltage terminal HVDD or the second power supply voltage terminal VDDA through one of the diode PDIO2 and the diode NDIO2, instead of being released to the external control circuit portion through the connection resistor RESD2, which avoids affecting the output stage.

Both the single-channel output circuit illustrated in FIG. 1A and the dual-channel output circuit illustrated in FIG. 1B require a separately fabricated combination of discharge diodes to provide an electrostatic discharge path, but these diodes fabricated on the substrate of an integrated circuit chip occupy a considerable chip area, resulting in the decrease in chip integration and the increase in manufacturing costs.

At least one embodiment of the present disclosure provides an electronic apparatus, and the electronic apparatus is, for example an integrated circuit chip or an electronic apparatus including the integrated circuit chip. The embodiment relates to an output circuit portion, which includes, for example, a functional circuit portion, an electrostatic protection circuit portion, and an external circuit portion. The electrostatic protection circuit portion is configured to electrically connect the functional circuit portion and the external circuit portion to transmit an electrical signal, and to provide electrostatic protection for the external circuit portion. The external circuit portion includes at least one external terminal and an external control circuit portion that is electrically connected to the external terminal, and the external control circuit portion is configured to control whether the electrical signal is transmitted to the external terminal. The electrostatic protection circuit portion is configured to use the external control circuit portion to perform electrostatic discharge. For example, the functional circuit portion, e.g., an output stage (e.g., used for buffering) of an electronic apparatus, generates the electrical signal to be output under the control of a control signal.

The electronic apparatus of the above-mentioned embodiment of the present disclosure can reduce the chip area occupied by the electrostatic discharge circuit portion, thereby improving the chip integration and reducing the manufacturing and design costs.

For example, in at least one example, the electrostatic protection circuit portion includes a connection circuit portion and a discharge path portion, and the connection circuit portion is electrically connected to the functional circuit portion and the external control circuit portion to transmit the electrical signal, and the connection circuit portion is configured to prevent static electricity from being transmitted to the functional circuit. The discharge path portion is electrically connected to the connection circuit portion through the external control circuit portion and is configured to provide an electrostatic discharge path.

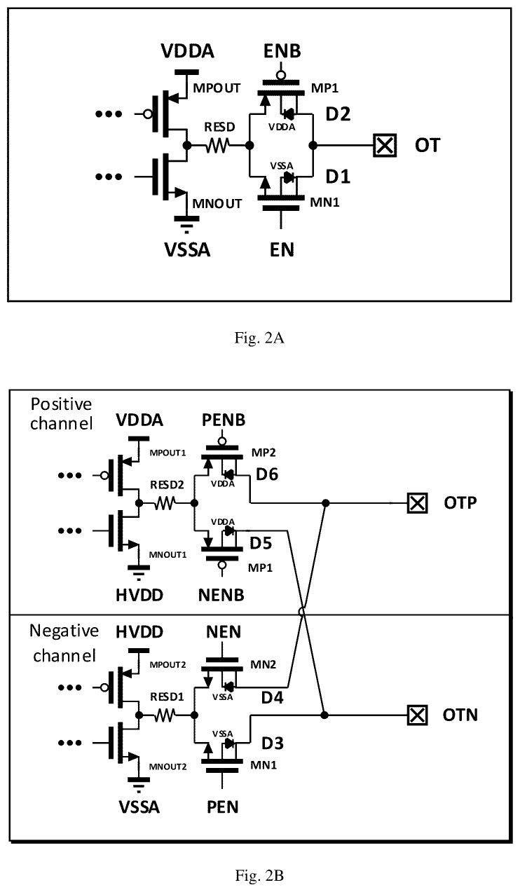

In at least one example, the output circuit portion is of a single-channel type. FIG. 2A illustrates a schematic diagram of an example of the single-channel output circuit portion.

As illustrated in FIG. 2A, in this example, the external control circuit portion includes

the first transistor MN1 of type N and the second transistor MP1 of type P, and the at least one external terminal includes the first external terminal OT. The source electrode of the first transistor MN1 is electrically connected to the connection circuit portion, and the drain electrode of the first transistor MN1 is electrically connected to the first external terminal OT. The source electrode of the second transistor MP1 is electrically connected to the connection circuit portion, and the drain electrode of the second transistor MP1 is electrically connected to the first external terminal OT. In addition, the gate electrode of the first transistor MN1 and the gate electrode of the second transistor MP1 are configured to receive respectively a pair of control signals EN and ENB that are inverted, so that the first transistor MN1 and the second transistor MP1 select whether to transmit an output signal under the control of the control signals EN and ENB. For example, because the control signals EN and ENB are inverted to each other, when the EN is at a high level, then the ENB is at a low level; otherwise, when the EN is at a low level, then the ENB is at a high level. For example, when the EN is at a high level and correspondingly the ENB is at a low level, both the first transistor MN1 and the second transistor MP1 are turned on, so that the output signal can be transmitted. In another example, the external control circuit portion may include only one of the first transistor MN1 and the second transistor MP1.

As illustrated in FIG. 2A, for example, the discharge path portion includes a first diode D1 and a second diode D2. The first diode D1 is arranged between the drain electrode of the first transistor MN1 and the substrate of the first transistor MN1, the drain electrode of the first transistor MN1 is determined as the cathode of the first diode D1, and the substrate of the first transistor MN1 is determined as the anode of the first diode D1 and is configured to receive the first power supply voltage VSSA. The second diode D2 is arranged between the drain electrode of the second transistor MP1 and the substrate of the second transistor MP1, and the drain electrode of the second transistor MP1 is determined as the anode of the second diode D2, and the substrate of the second transistor MP1 is determined as the cathode of the second diode D2 and is configured to receive the second power supply voltage VDDA. The first power supply voltage VSSA is lower than the second power supply voltage VDDA. For example, the first power supply voltage VSSA is the ground voltage. In the example where the external control circuit portion includes only one of the first transistor MN1 and the second transistor MP1, the discharge path portion includes one of the first diode D1 and the second diode D2 (e.g., the first diode D1), and correspondingly, the discharge path portion further includes another separately fabricated diode (e.g., the second diode D2) corresponding to one of the two diodes.

For example, the first diode D1 at least partially includes a parasitic diode arranged between the drain electrode of the first transistor MN1 and the substrate of the first transistor MN1. The second diode D2 at least partially includes a parasitic diode arranged between the drain electrode of the second transistor MP1 and the substrate of the second transistor MP1. For example, the first diode D1 and/or the second diode D2 can be implemented completely through the parasitic diode caused by the corresponding transistor. Further, the shape, area size, etc., of the electrodes of the corresponding transistor can be appropriately adjusted so that the first diode D1 and/or the second diode D2 can be provided in the form of the parasitic diode.

As illustrated in FIG. 2A, for example, the connection circuit portion includes a first connection resistor RESD, and the resistance value of the first connection resistor RESD is set to be greater than the on-resistance value of the first diode D1 and the on-resistance value of the second diode D2. Therefore, when static electricity is generated on the external terminal OT, the static electricity can be released through the first diode D1 or the second diode D2. For another example, the resistance value of the first connection resistor RESD is set to be greater than the on-resistance value of the first transistor MN1 and the on-resistance value of the second transistor MP1.

As illustrated in FIG. 2A, for example, the functional circuit portion as described above includes an output stage, and the output stage includes a first functional transistor MNOUT of type N and a second functional transistor MPOUT of type P. The drain electrode of the first functional transistor MNOUT and the drain electrode of the second functional transistor MPOUT are electrically connected to the first connection resistor RESD, so that the output signal obtained can be transmitted to the external control circuit portion through the first connection resistor RESD, and can be further transmitted to the external terminal OT used to output through the external control circuit portion.

In the single-channel output circuit portion of the electronic apparatus in the example above, compared with the single-channel output circuit portion illustrated in FIG. 1A, the position of the connection circuit portion included in the electrostatic protection circuit portion relative to the external control circuit portion is changed, and at least partial structure of the transistors in the external control circuit portion is reused to provide the diodes that are used as electrostatic discharge paths, so that these diodes can be prevented from occupying the chip area, the chip integration is improved and the costs are reduced.

In at least one example, the output circuit portion is of a dual-channel type. FIG. 2B illustrates a schematic diagram of an example of the dual-channel output circuit portion.

As illustrated in FIG. 2B, in this example, the dual-channel output circuit portion includes a positive channel and a negative channel. The external control circuit portion includes a third transistor MN1 of type N and a fourth transistor MN2 of type N that are used for the negative channel, and a fifth transistor MP1 of type P and a sixth transistor MP2 of type P that are used for the positive channel. At least one external terminal includes a first external terminal OTN used for the negative channel and a second external terminal OTP used for the positive channel.

For example, the source electrode of the third transistor MN1 is electrically connected to the connection circuit portion, and the drain electrode of the third transistor MN1 is electrically connected to the first external terminal OTN. The source electrode of the fourth transistor MN2 is electrically connected to the connection circuit portion, and the drain electrode of the fourth transistor MN2 is electrically connected to the second external terminal OTP.

The source electrode of the fifth transistor MP1 is electrically connected to the connection circuit portion, and the drain electrode of the fifth transistor MP1 is electrically connected to the first external terminal OTN. The source electrode of the sixth transistor MP2 is electrically connected to the connection circuit portion, and the drain electrode of the sixth transistor MP2 is electrically connected to the second external terminal OTP.

The gate electrode of the third transistor MN1 and the gate electrode of the sixth transistor MP2 are configured to receive respectively a first pair of control signals PEN and PENB which are inverted to each other. The gate electrode of the fourth transistor MN2 and the gate electrode of the fifth transistor MP1 are configured to receive respectively a second pair of control signals NEN and NENB which are inverted to each other.

For example, the discharge path portion includes a third diode D3, a fourth diode D4, a fifth diode D5 and a sixth diode D6.

The third diode D3 is arranged between the drain electrode of the third transistor MN1 and the substrate of the third transistor MN1, the drain electrode of the third transistor MN1 is determined as the cathode of the third diode D3, and the substrate of the third transistor MN1 is determined as the anode of the third diode D3 and is configured to receive the first power supply voltage VSSA. The fourth diode D4 is arranged between the drain electrode of the fourth transistor MN2 and the substrate of the fourth transistor MN2, and the drain electrode of the fourth transistor MN2 is determined as the anode of the fourth diode D4, and the substrate of the fourth transistor MN2 is determined as the cathode of the fourth diode D4 and is configured to receive the first power supply voltage VSSA.

The fifth diode D5 is arranged between the drain electrode of the fifth transistor MP1 and the substrate of the fifth transistor MP1, the drain electrode of the fifth transistor MP1 is determined as the cathode of the fifth diode D5, and the substrate of the fifth transistor MP1 is used as the anode of the fifth diode D5 and is configured to receive the second power supply voltage VDDA. The sixth diode D6 is arranged between the drain electrode of the sixth transistor MP2 and the substrate of the sixth transistor MP2, and the drain electrode of the sixth transistor MP2 is determined as the anode of the sixth diode D6, and the substrate of the sixth transistor MP2 is determined as the cathode of the sixth diode D6 and is configured to receive the second power supply voltage VDDA. Herein, similarly, the first power supply voltage VSSA is lower than the second power supply voltage VDDA.

For example, the functional circuit portion includes a first functional circuit sub-portion and a second functional circuit sub-portion, and the connection circuit portion includes a second connection resistor RESD1 and a third connection resistor RESD2.

The second connection resistor RESD1 is connected between the first functional circuit sub-portion and the source electrodes of the third transistor MN1 and the fourth transistor MN2, and the resistance value of the second connection resistor RESD1 is set to be greater than the on-resistance value of the third diode D3 and the on-resistance value of the fourth diode D4. For example, the resistance value of the second connection resistor RESD1 is further set to be greater than the on-resistance value of the third transistor MN1 and the on-resistance value of the fourth transistor MN2.

The third connection resistor RESD2 is connected between the second functional circuit sub-portion and the source electrodes of the fifth transistor MP1 and the sixth transistor MP2, and the resistance value of the third connection resistor is set to be greater than the on-resistance value of the fifth diode D5 and the on-resistance value of the sixth diode D6. For example, the resistance value of the third connection resistor RESD2 is further set to be greater than the on-resistance value of the fifth transistor MP1 and the on-resistance value of the sixth transistor MP2.

Therefore, when static electricity is generated on the external terminal OTN, the static electricity can be released through the third diode D3 or the fifth diode D5. When static electricity is generated on the external terminal OTP, the static electricity can be released through the fourth diode D4 or the sixth diode D6.

For example, the first functional circuit sub-portion includes a third functional transistor of type N and a fourth functional transistor of type P. The drain electrode of the third functional transistor and the drain electrode of the fourth functional transistor are electrically connected to the second connection resistor RESD1, so that the first output signal obtained can be transmitted to the external control circuit portion through the second connection resistor RESD1, and can be further transmitted to the external terminal for output through the external control circuit portion.

The second functional circuit sub-portion includes a fifth functional transistor of N type and a sixth functional transistor of P type, and the drain electrode of the fifth functional transistor and the drain electrode of the sixth functional transistor are electrically connected to the third connection resistor RESD2, so that the obtained second output signal can be transmitted to the external control circuit portion through the second connection resistor RESD1, and can be further transmitted to the external terminal used to output through the external control circuit portion.

For example, the third diode D3 at least partially includes a parasitic diode arranged between the drain electrode of the third transistor MN1 and the substrate of the third transistor MN1, and the fourth diode D4 at least partially includes a parasitic diode arranged between the drain electrode of the fourth transistor MN2 and the substrate of the fourth transistor MN2. For example, the fifth diode D5 at least partially includes a parasitic diode arranged between the drain electrode of the fifth transistor MP1 and the substrate of the fifth transistor MP1, and the sixth diode D6 at least partially includes a parasitic diode arranged between the drain electrode of the sixth transistor MP2 and the substrate of the sixth transistor MP2.

For example, any of the above third diode D3 to the sixth diode D6 can be implemented completely through the parasitic diode caused by the corresponding transistor. Further the shape, area size, etc., of the electrodes of the corresponding transistor can be appropriately adjusted, so that one of the corresponding third diode D3 to the sixth diode D6 can be provided in the form of a parasitic diode.

Similarly, in the dual-channel output circuit portion of the electronic apparatus in the example above, compared with the dual-channel output circuit portion illustrated in FIG. 1B, the position of the connection circuit portion included in the electrostatic protection circuit portion relative to the external control circuit portion is changed, and at least partial structure of the transistors in the external control circuit portion is reused to provide diodes that are used as electrostatic discharge paths, so that these diodes can be prevented from occupying the chip area, the chip integration is improved and the costs are reduced.

The following, by means of an integrated circuit layout, further illustrates that the output circuit portion of the electronic apparatus in the embodiments of the present disclosure has a smaller chip occupying area.

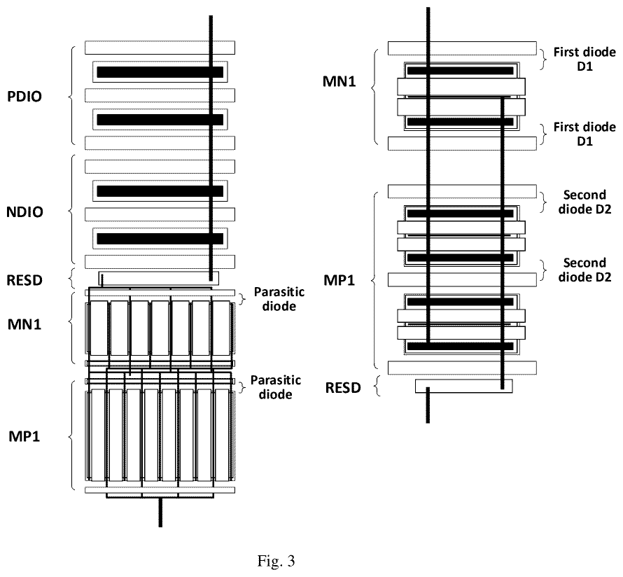

FIG. 3 illustrates an exemplary layout schematic diagram (left) of the single-channel output circuit portion illustrated in FIG. 1A and an exemplary layout schematic diagram (right) of the single-channel output circuit portion according to at least one embodiment of the present disclosure illustrated in FIG. 2A. In FIG. 3, the boxed sections represent a doped region, an active region, metallization (e.g., polysilicon or tungsten silicide, etc.), and the black line or square section represents the metal line or metal electrode.

As illustrated in FIG. 3, for the single-channel output circuit illustrated in FIG. 1A, on the surface of the substrate (not explicitly illustrated in FIG. 3), a combination of discharge diodes, a connection resistor RESD and an external control circuit portion are arranged sequentially in the longitudinal direction from the top to the bottom of the diagram. The combination of discharge diodes includes a diode PDIO and a diode NDIO, each diode includes two PN junctions that are arranged side by side and formed by a laterally extended doping region. The connection resistor RESD is also formed by a laterally extended doping region. The external control circuit portion includes an N-type transistor MN1 and a P-type transistor MP1, and the active region of each transistor includes a plurality of longitudinally extended doping regions. Moreover, as illustrated in FIG. 3, although the N-type transistor MN1 and the P-type transistor MP1 have their own parasitic diodes, due to the limitation of the chip area, the size of the laterally extended doping region corresponding to the transistor is small, which makes the breakdown voltage of these parasitic diodes large. As illustrated in FIG. 3, the chip area occupied by the diode PDIO and the diode NDIO is comparable to, or even larger than the chip area occupied by the N-type transistor MN1 and the P-type transistor MP1.

As illustrated in FIG. 3, for the single-channel output circuit illustrated in FIG. 2A, on the surface of the substrate, the external control circuit portion and the connection resistor RESD are arranged sequentially in the longitudinal direction from the top to the bottom of the FIG. 3. Compared with the single-channel output circuit illustrated in FIG. 1A, the single-channel output circuit illustrated in FIG. 2A no longer includes the combination of discharge diodes fabricated separately, so that there is sufficient area to arrange the transistors included in the external control circuit portion. The external control circuit portion includes the first transistor MN1 of type N and the second transistor MP1 of type P. The first transistor MN1 and the second transistor MP1 respectively include a plurality of doping regions that are laterally extended and parallel. The first diode D1 and the second diode D2 are included in the discharge path portion are the parasitic diodes (or at least part) of the first transistor MN1 and the second transistor MP1, so that the first diode D1 and the second diode D2 have the electrical properties required for implementing the discharge path. For example, compared with the N-type first transistor MN1 and the P-type transistor MP1 in the single-channel output circuit illustrated in FIG. 1A, the N-type first transistor MN1 and the P-type second transistor MP1 illustrated in FIG. 2A can have a larger active region (but do not significantly increase the chip area occupied by the transistors), thereby forming a larger PN junction, so that the breakdown voltage of these parasitic diodes meets the required performance.

Although no specific layout diagram is used to compare the dual-channel data circuit portions in FIGS. 1B and 2B, it is understood that the dual-channel output circuit portions in FIG. 1B and FIG. 2B can also be compared in a similar layout diagram manner.

Although components in the layout diagram of the output circuit portion illustrated in FIG. 3 are arranged along the longitudinal direction, it is understood that the embodiments of the present disclosure are not limited to the above exemplary layout. In the embodiments of the present disclosure, the components in the layout diagram may also be arranged along another direction (such as lateral direction), so as to accommodate different design requirements.

The electronic apparatus in at least one embodiment of the present disclosure may be implemented, for example, as various types of integrated circuit chips, such as memory chips, logic chips, DSP chips, FPGA chips, digital processor (DSP) chips, etc., and for example, may be used for mobile phones, tablet computers, laptop computers, e-books, game consoles, televisions, digital photo frames, navigators, and may be any combination of data processing apparatuses and hardware, and the embodiments of the present disclosure are not limited to this.

Although the present disclosure has been described in detail in the above with general descriptions and specific embodiments, some modifications or improvements can be made on the basis of the embodiments of the present disclosure, which is obvious to those skilled in the art. Therefore, such modifications or improvements made on the basis of not deviating from the spirit of this disclosure fall within the scope of protection of this disclosure requirement.

There are the following points to be clarified regarding this disclosure:
(1) The drawings attached to the embodiments of the present disclosure only relate to the structures related to the embodiments of the present disclosure, and other structures may refer to the usual design.
(2) For clarity, in the drawings used to describe the embodiments of the present disclosure, the thickness of the layers or areas is enlarged or reduced, i.e., the drawings are not drawn to actual scale.
(3) In the absence of conflict, the embodiments of the present disclosure and the features in the embodiments may be combined with each other to obtain new embodiments.

The foregoing is only a specific embodiment of the present disclosure, but the scope of protection of the present disclosure is not limited to this, and the scope of protection of this disclosure shall be subject to the scope of protection of the claimed claims.

1. An electronic apparatus, comprising a functional circuit portion, an electrostatic protection circuit portion and an external circuit portion,
wherein the electrostatic protection circuit portion is configured to electrically connect the functional circuit portion and the external circuit portion to transmit an electrical signal, and to provide electrostatic protection for the external circuit portion;
the external circuit portion comprises at least one external terminal and an external control circuit portion that is electrically connected to the external terminal, and the external control circuit portion is configured to control whether the electrical signal is transmitted to the external terminal; and
the electrostatic protection circuit portion is configured to use the external control circuit portion to perform electrostatic discharge.

2. The electronic apparatus according to claim 1, wherein the electrostatic protection circuit portion comprises a connection circuit portion and a discharge path portion,
the connection circuit portion is electrically connected to the functional circuit portion and the external control circuit portion to transmit the electrical signal, and is configured to prevent static electricity from being transmitted to the functional circuit portion; and
the discharge path portion is electrically connected to the connection circuit portion through the external control circuit portion and is configured to provide an electrostatic discharge path.

3. The electronic apparatus according to claim 2, wherein the external control circuit portion comprises a first transistor of type N and a second transistor of type P, and the at least one external terminal comprises a first external terminal,
a source electrode of the first transistor is electrically connected to the connection circuit portion, and a drain electrode of the first transistor is electrically connected to the first external terminal,
a source electrode of the second transistor is electrically connected to the connection circuit portion, and a drain electrode of the second transistor is electrically connected to the first external terminal, and
a gate electrode of the first transistor and a gate electrode of the second transistor are configured to receive respectively a pair of control signals which are inverted;
the discharge path portion comprises a first diode and a second diode,
the first diode is between the drain electrode of the first transistor and a substrate of the first transistor, the drain electrode of the first transistor is determined as a cathode of the first diode, and the substrate of the first transistor is determined as an anode of the first diode and is configured to receive a first power supply voltage; and
the second diode is between the drain electrode of the second transistor and a substrate of the second transistor, the drain electrode of the second transistor is determined as an anode of the second diode, the substrate of the second transistor is determined as the cathode of the second diode and is configured to receive a second power supply voltage, and the first power supply voltage is lower than the second power supply voltage.

4. The electronic apparatus according to claim 3, wherein the connection circuit portion comprises a first connection resistor, and a resistance value of the first connection resistor is set to be greater than an on-resistance value of the first diode and an on-resistance value of the second diode.

5. The electronic apparatus according to claim 4, wherein the functional circuit portion comprises a first functional transistor of type N and a second functional transistor of type P, and a drain electrode of the first functional transistor and a drain electrode of the second functional transistor are electrically connected to the first connection resistor.

6. The electronic apparatus according to claim 3, wherein the first diode at least partially comprises a parasitic diode between the drain electrode of the first transistor and the substrate of the first transistor, and
the second diode at least partially comprises a parasitic diode between the drain electrode of the second transistor and the substrate of the first transistor.

7. The electronic apparatus according to claim 2, wherein the external control circuit portion comprises a third transistor of type N, a fourth transistor of type N, a fifth transistor of type P and a sixth transistor of type P, and the at least one external terminal comprises a first external terminal and a second external terminal,
a source electrode of the third transistor is electrically connected to the connection circuit portion, and a drain electrode of the third transistor is electrically connected to the first external terminal,
a source electrode of the fourth transistor is electrically connected to the connection circuit portion, and a drain electrode of the fourth transistor is electrically connected to the second external terminal,
a source electrode of the fifth transistor is electrically connected to the connection circuit portion, and a drain electrode of the fifth transistor is electrically connected to the first external terminal,
a source electrode of the sixth transistor is electrically connected to the connection circuit portion, and a drain electrode of the sixth transistor is electrically connected to the second external terminal,
a gate electrode of the third transistor and a gate electrode of the sixth transistor are configured to receive respectively a first pair of control signals which are inverted to each other,
a gate electrode of the fourth transistor and a gate electrode of the fifth transistor are configured to receive respectively a second pair of control signals which are inverted to each other,
the discharge path portion comprises a third diode, a fourth diode, a fifth diode and a sixth diode,
the third diode is between the drain electrode of the third transistor and a substrate of the third transistor, the drain electrode of the third transistor is determined as a cathode of the third diode, the substrate of the third transistor is determined as an anode of the third diode and is configured to receive a first power supply voltage,
the fourth diode is between the drain electrode of the fourth transistor and a substrate of the fourth transistor, the drain electrode of the fourth transistor is determined as an anode of the fourth diode, the substrate of the fourth transistor is determined as a cathode of the fourth diode and is configured to receive the first power supply voltage,
the fifth diode is between the drain electrode of the fifth transistor and a substrate of the fifth transistor, the drain electrode of the fifth transistor is determined as a cathode of the fifth diode, the substrate of the fifth transistor is determined as an anode of the fifth diode and is configured to receive a second power supply voltage,
the sixth diode is between the drain electrode of the sixth transistor and a substrate of the sixth transistor, the drain electrode of the sixth transistor is determined as an anode of the sixth diode, the substrate of the sixth transistor is determined as a cathode of the sixth diode and is configured to receive the second power supply voltage, and
the first power supply voltage is lower than the second power supply voltage.

8. The electronic apparatus according to claim 7, wherein the functional circuit portion comprises a first functional circuit sub-portion and a second functional circuit sub-portion,
the connection circuit portion comprises a second connection resistor and a third connection resistor,
the second connection resistor is connected between the first functional circuit sub-portion, and the source electrode of the third transistor and the source electrode of the fourth transistor, and a resistance value of the second connection resistor is set to be greater than an on-resistance value of the third diode and an on-resistance value of the fourth diode, and
the third connection resistor is connected between the second functional circuit sub-portion, and the source electrode of the fifth transistor and the source electrode of the sixth transistor, and a resistance value of the third connection resistor is set to be greater than an on-resistance value of the fifth diode and an on-resistance value of the sixth diode.

9. The electronic apparatus according to claim 8, wherein the first functional circuit sub-portion comprises a third functional transistor of type N and a fourth functional transistor of type P, and a drain electrode of the third functional transistor and a drain electrode of the fourth functional transistor are electrically connected to the second connection resistor, and
the second functional circuit sub-portion comprises a fifth functional transistor of type N and a sixth functional transistor of type P, and a drain electrode of the fifth functional transistor and a drain electrode of the sixth functional transistor are electrically connected to the third connection resistor.

10. The electronic apparatus according to claim 7, wherein the third diode at least partially comprises a parasitic diode between the drain electrode of the third transistor and the substrate of the third transistor,
the fourth diode at least partially comprises a parasitic diode between the drain electrode of the fourth transistor and the substrate of the fourth transistor,
the fifth diode at least partially comprises a parasitic diode between the drain electrode of the fifth transistor and the substrate of the fifth transistor, and
the sixth diode at least partially comprises a parasitic diode between the drain electrode of the sixth transistor and the substrate of the sixth transistor.
